(19) United States
(12) Patent Application Publication
(10) Pub. No.: US 2025/0275453 A1
(43) Pub. Date: Aug. 28, 2025

(54) Display Apparatus

(71) Applicant: LG Display Co., Ltd., Seoul (KR)

(72) Inventors: Wangeon Sim, Paju-si (KR); Sohee Kim, Gumi-si (KR)

(21) Appl. No.: 19/013,670

(22) Filed: Jan. 8, 2025

(30) Foreign Application Priority Data
Feb. 28, 2024 (KR) 10-2024-0029208

(51) Int. Cl. H10K 59/80

(52) U.S. Cl. CPC H10K 59/8792; H10K 59/873

(57) ABSTRACT

A display apparatus includes a display panel including a substrate in which a display area in which a plurality of pixels is disposed and a non-display area in an outer periphery of the display area are defined. The display apparatus further includes a first plate disposed below the display panel. The display apparatus further includes a black layer disposed on a bottom surface of the first plate. The display apparatus further includes a printed circuit board disposed below the first plate. The display apparatus further includes a first adhesive layer which bonds the first plate and the printed circuit board. A bottom surface of the first plate includes a center area and an edge area which encloses the center area and includes a first area and a second area and the black layer is disposed in the first area among the first area and the second area.

### CROSS-REFERENCE TO RELATED APPLICATION

This application claims the priority of Republic of Korea Patent Application No. 10-2024-0029208 filed on Feb. 28, 2024, which is hereby incorporated by reference in its entirety.

### BACKGROUND

### Field

The present disclosure relates to a display apparatus.

### Description of the Related Art

As it enters the information era, a field of a display apparatus which visually expresses electrical information signals has been rapidly developed and studies are continued to improve performances of various display apparatuses, such as a thin-thickness, a light weight, and low power consumption.

As exemplary display apparatus, there are a liquid crystal display (LCD), an electro-wetting display (EWD), and an organic light emitting display (OLED).

Among them, the electroluminescence display apparatus is a self-emitting display apparatus so that a separate light source is not necessary, which is different from the liquid crystal display apparatus. Therefore, the electroluminescence display apparatus may be manufactured to have a light weight and a thin-thickness. Further, since the electroluminescent display apparatus is advantageous not only in terms of power consumption due to the low voltage driving, but also in terms of color implementation, a response speed, a viewing angle, a contrast ratio (CR), it is expected to be utilized in various fields.

### SUMMARY

An object to be achieved by an exemplary embodiment of the present disclosure is to provide a display apparatus which suppresses occurrence of stain defects of a display panel due to exposure to external light on a rear surface of a display panel.

Another object to be achieved by an exemplary embodiment of the present disclosure is to provide a display apparatus which guides the bending of the display panel.

Further, still another object to be achieved by an exemplary embodiment of the present disclosure is to provide a display apparatus which guides placement positions of components which are disposed on a rear surface of the display panel.

Objects of the present disclosure are not limited to the above-mentioned objects, and other objects, which are not mentioned above, can be clearly understood by those skilled in the art from the following descriptions.

In order to achieve the objects as described above, according to an aspect of the present disclosure, a display apparatus includes a display panel including a substrate in which a display area in which a plurality of pixels is disposed and a non-display area in which an outer periphery of the display area are defined; a first plate disposed below the display panel; a black layer disposed on a bottom surface of the first plate; a printed circuit board disposed below the first plate; and a first adhesive layer which bonds the first plate and the printed circuit board. At this time, a bottom surface of the first plate includes a center area and an edge area which encloses the center area and includes a first area and a second area and the black layer is disposed in the first area among the first area and the second area.

Other detailed matters of the exemplary embodiments are included in the detailed description and the drawings.

According to the exemplary embodiment of the present disclosure, in the display apparatus, a layer which suppresses exposure to external light is disposed on a rear surface of the display panel to reduce a damage of the display panel and suppress stain defects.

According to the exemplary embodiment of the present disclosure, in the display apparatus, the exposure to external light from a rear surface of the display panel is suppressed, but a panel alignment mark required to bend the display panel is exposed to guide the bending of the display panel. By doing this, misalignment of components which are disposed in a bending area is suppressed.

According to the exemplary embodiment of the present disclosure, in the display apparatus, the exposure to external light from a rear surface of the display panel is suppressed, but placement of a printed circuit board which is disposed on the rear surface of the display panel is guided to suppress misalignment.

According to the exemplary embodiment of the present disclosure, in the display apparatus, a process of attaching a separate blocking film on a rear surface of the display panel is omitted, thereby simplifying the process and reducing a production cost.

The effects of the present disclosure are not limited to the aforementioned effects, and other effects, which are not mentioned above, will be apparently understood to a person having ordinary skill in the art from the following description.

The effects of the present disclosure are not limited to the aforementioned effects, and other effects, which are not mentioned above, will be apparently understood to a person having ordinary skill in the art from the following description.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a block diagram of a display apparatus according to an exemplary embodiment of the present disclosure;

FIG. 2 is a front view of a display apparatus according to an exemplary embodiment of the present disclosure;

FIG. 3 is a plan view of a substrate of a display panel as seen from a front side according to an exemplary embodiment of the present disclosure;

FIG. 4 is a cross-sectional view taken along the line I-I′ of FIG. 2 according to an exemplary embodiment of the present disclosure;

FIG. 5 is a plan view of a first plate as seen from a rear surface of a display panel according to an exemplary embodiment of the present disclosure;

FIG. 6A is a plan view illustrating an example of an adhesive layer disposed below a first plate according to an exemplary embodiment of the present disclosure;

FIG. 6B is a plan view illustrating another example of an adhesive layer disposed below a first plate according to an exemplary embodiment of the present disclosure;

FIG. 7 is a rear view of a display device including a first plate according to an exemplary embodiment of the present disclosure;

FIG. 8 is a cross-sectional view taken along the line II-II′ of FIG. 7 according to an exemplary embodiment of the present disclosure;

FIG. 9 is a cross-sectional view taken along the line III-III′ of FIG. 7 according to an exemplary embodiment of the present disclosure;

FIG. 10 is a cross-sectional view taken along the line IV-IV′ of FIG. 7 according to an exemplary embodiment of the present disclosure;

FIG. 11 is a plan view of a first plate as seen from a rear surface of a display panel according to another exemplary embodiment of the present disclosure;

FIG. 12A is a plan view illustrating an example of an adhesive layer disposed below a first plate according to another exemplary embodiment of the present disclosure;

FIG. 12B is a plan view illustrating another example of an adhesive layer disposed below a first plate according to another exemplary embodiment of the present disclosure;

FIG. 13 is a rear view of a display device including a first plate according to another exemplary embodiment of the present disclosure;

FIG. 14 is a cross-sectional view taken along the line V-V′ of FIG. 13 according to an exemplary embodiment of the present disclosure;

FIG. 15 is a cross-sectional view taken along the line VI-VI′ of FIG. 13 according to an exemplary embodiment of the present disclosure; and

FIG. 16 is a cross-sectional view taken along the line VII-VII′ of FIG. 13 according to an exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure.

The terms such as “including,” “having,” and “comprising” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly” is not used.

When an element or layer is referred to as being “on” another element or layer, it may be directly on the other element or layer, or intervening elements or layers may be present therebetween. When a component is “linked”, “coupled”, or “connected” to another component, the component may be directly linked or connected to the other component. However, unless specifically stated otherwise, it should be understood that a third component may be interposed between the components which may be indirectly linked or connected.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawings are illustrated for convenience of explanation and are not limited to the size and the thickness of the component illustrated in embodiments of the present disclosure.

The features of various embodiments of the present disclosure can be partially or entirely coupled to or combined with each other and can be interlocked and operated in technically various ways, and respective embodiments can be carried out independently of or in association with each other.

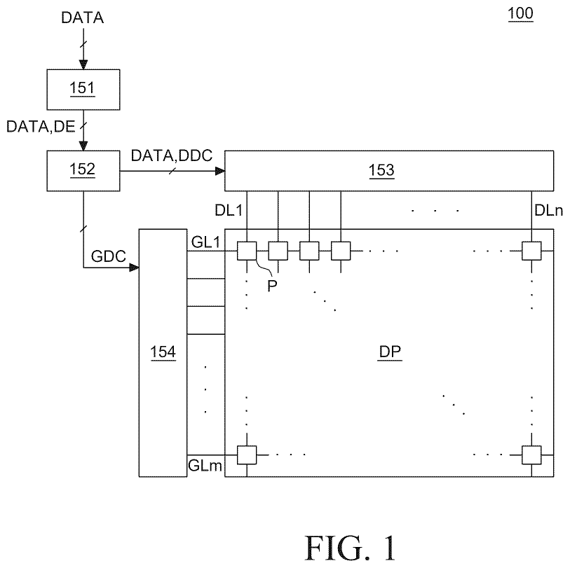

FIG. 1 is a block diagram of a display apparatus according to an exemplary embodiment of the present disclosure.

Referring to FIG. 1, a display apparatus 100 according to an exemplary embodiment of the present disclosure includes an image processor 151, a timing controller 152, a data driver 153, a gate driver 154, and a display panel DP.

The image processor 151 outputs a data signal DATA supplied from the outside and a driving signal including a data enable signal DE. The image processor 151 may output a driving signal including one or more of a vertical synchronization signal, a horizontal synchronization signal, and a clock signal in addition to the data enable signal DE.

The timing controller 152 is supplied with a driving signal including a data enable signal DE and a data signal DATA from the image processor 152. The timing controller 152 outputs a gate timing control signal GDC for controlling an operation timing of the gate driver 154 based on the driving signal. The timing controller 152 outputs a data signal DATA supplied from the image processor 151 and a data timing control signal DDC for controlling an operation timing of the data driver 153.

The data driver 153 samples and latches the data signal DATA supplied from the timing controller 152 in response to the data timing control signal DDC supplied from the timing controller 152 to convert the data signal into a gamma reference voltage and output the converted gamma reference voltage. Further, the data driver 153 outputs a data signal through data lines DL1 to DLn.

The gate driver 154 may output the gate signal in response to the gate timing control signal GDC supplied from the timing controller 152 and at this time, shifts a level of the gate voltage to output a gate signal. Further, the gate driver 154 outputs a gate signal through gate lines GL1 to GLm.

The display panel DP includes a plurality of pixels P and each of the plurality of pixels P emits light in response to the data signal and the gate signal supplied from the data driver 153 and the gate driver 154, respectively, to display images.

One pixel P is configured by a plurality of sub pixels. For example, one pixel includes three or more sub pixels which emit different color light. For example, in the display apparatus 100 according to the exemplary embodiment of the present disclosure, one pixel P includes sub pixels which emit red light, green light, and blue light. However, the number of sub pixels included in one pixel P is not limited and for example, a sub pixel which emits white light may be further included, in addition to the sub pixels which emit red light, green light, and blue light.

On the display panel DP, a plurality of gate lines GL1 to GLm extending in a first direction and a plurality of data lines DL1 to DLn extending in a second direction which is different from the first direction are disposed to intersect. Pixels P are defined at intersections of the plurality of gate lines and data lines on the display panel DP.

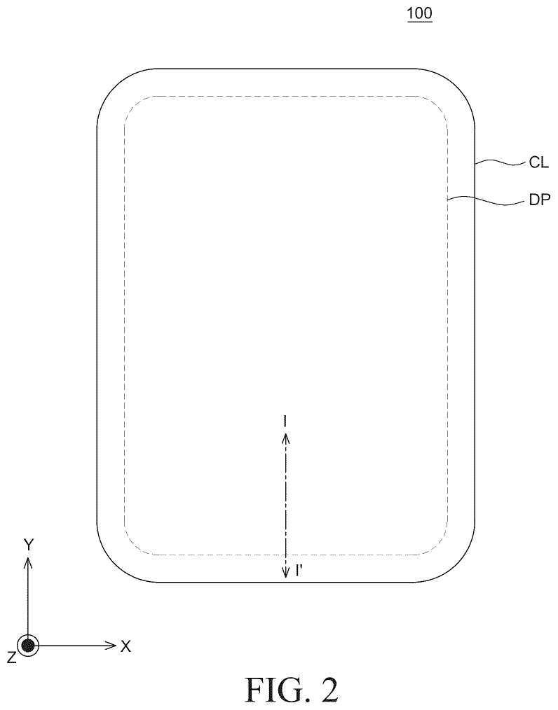

FIG. 2 is a front view of a display apparatus according to an exemplary embodiment of the present disclosure.

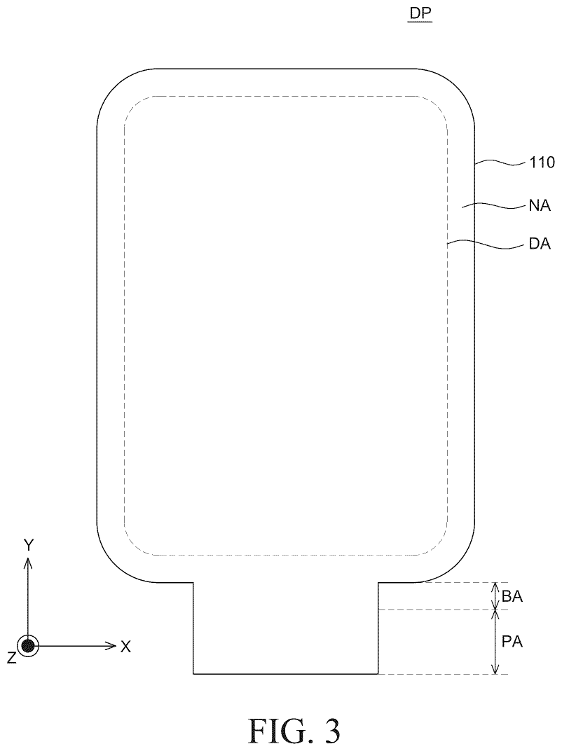

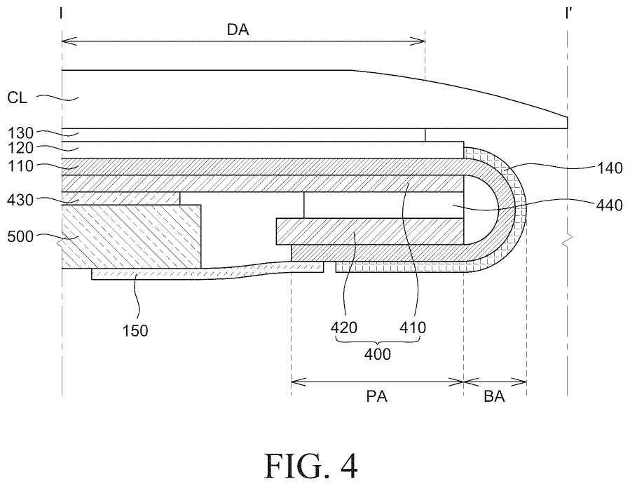

FIG. 3 is a plan view of a substrate of a display panel as seen from a front side according to an exemplary embodiment of the present disclosure. FIG. 4 is a cross-sectional view taken along the line I-I′ of FIG. 2 according to an exemplary embodiment of the present disclosure.

In the present specification, a direction in which the pixel P emits light on the display panel DP (that is, a direction in which an image is displayed) is referred to as a front surface of the display panel DP and an opposite direction of the direction in which the pixel P emits light is referred to as a rear surface of the display panel DP. For example, as illustrated in FIGS. 2 and 3, a direction of the front surface of the display pane DP is defined as a Z axis and a direction of the rear surface of the display panel DP is defined as a −Z axis.

When the placement structure of each component of the display apparatus 100 is described in the present specification, the description will be made with respect to a direction in which the image is displayed on the display panel DP. For example, components which are disposed in a front direction of the display panel DP are described to be disposed on or above the display panel DP and components which are disposed in a rear direction of the display panel DP are described to be disposed under or below the display panel DP.

As illustrated in FIGS. 2 and 4, the display apparatus 100 includes a display panel DP including a substrate 110, a cover layer CL disposed above the display panel DP, and an optical layer 120 and a third adhesive layer 130 disposed between the substrate 110 of the display panel DP and the cover layer CL. Further, the display apparatus 100 includes a back plate 400, a first adhesive layer 430, a second adhesive layer 440, a reinforcement member 140, a flexible film unit 150, and a printed circuit board 500 which are disposed below the substrate 110 of the display panel DP. At this time, the back plate 400 includes a first plate 410 and a second plate 420.

The substrate 110 is configured to support various components included in the display apparatus 100. The substrate 110 is formed of an insulating material. Further, the substrate 110 is formed of a transparent material. Further, the substrate 110 may be a rigid substrate or a flexible substrate which is bendable, foldable, or rollable. For example, the substrate 110 may be formed of a plastic material, such as polyimide (PI). When the substrate 110 is formed of a plastic material (for example, polyimide (PI)) having flexibility, the manufacturing process of the display apparatus 100 is performed under a circumstance when a support substrate formed of glass is disposed below the substrate 110 and the support substrate may be released after completing the manufacturing process of the display apparatus 100.

As illustrated in FIG. 3, the substrate 110 of the display panel DP is defined by a display area DA in which a plurality of pixels P which implement an image is disposed and a non-display area NA in which a plurality of pixels P are not disposed, at an outer periphery of the display area DA. The non-display area NA of the substrate 110 is defined as a surrounding area which encloses around the display area DA, a bending area BA which extends from one side of the surrounding area and is bent toward the rear surface of the display panel DP, and a pad area PA extending from the bending area BA. Further, referring to FIG. 4, as the substrate 110 is bent in the bending area BA, the pad area PA of the substrate 110 may be disposed to at least partially overlap the display area DA on the rear surface of the display panel DP.

In the display area DA of the substrate 110, a plurality of sub pixels each including a light emitting diode and a thin film transistor for driving the light emitting diode and a pixel array unit including signal lines, such as a gate line GL, a data line DL, and a pixel driving power line may be disposed. Further, an encapsulation unit which covers a pixel array unit may be disposed on the substrate 110 and the encapsulation unit suppresses oxygen, moisture, and foreign materials from permeating into the light emitting diode layer. The encapsulation unit is formed with a multi-layered structure in which an organic material layer and an inorganic material layer are alternately laminated, but is not limited thereto.

In the display area DA of the substrate 110, a display unit for displaying an image and a circuit unit for driving the display unit may be disposed.

For example, when the display apparatus 100 is an organic light emitting display apparatus, the display unit includes a light emitting diode which includes an anode, an emission layer on an anode, and a cathode on the emission layer. At this time, the display unit includes an organic emission layer as an emission layer and further includes a hole transport layer, a hole injection layer, an electron injection layer, and an electron transport layer together with the organic emission layer. However, when the display apparatus 100 is a liquid crystal display apparatus, the display unit may be configured to include a liquid crystal layer. Hereinafter, for the convenience of description, it is assumed that the display apparatus 100 is an organic light emitting display apparatus, but is not limited thereto.

The circuit unit includes various transistors, a capacitor, and wiring lines for driving the light emitting diodes and specifically, may be formed of various components, such as a driving transistor, a switching transistor, a storage capacitor, a gate line, and a data line, but is not limited thereto.

The sub pixel of the display apparatus 100 includes a switching transistor, a driving transistor, a capacitor, and a light emitting diode. The light emitting diode operates to emit light according to a driving current formed by the driving transistor. The switching transistor may perform a switching operation such that a data signal supplied through the data line DL is stored in a capacitor as a data voltage in response to a gate signal supplied through the gate line GL. The driving transistor operates to flow a constant driving current between the high potential power line and the low potential power line in response to the data voltage stored in the capacitor.

It has been described above that in the display apparatus 100 according to the exemplary embodiment of the present disclosure, one sub pixel is configured with a 2T (transistor) 1C (capacitor) structure including one switching transistor, one driving transistor, and one capacitor as an example. However, when a compensation circuit is further included, the sub pixel may be configured in various structures, such as 3T1C, 4T2C, 5T2C, 6TIC, 6T2C, 7T1C, or 7T2C. The compensation circuit is a circuit for compensating for a threshold voltage of the driving transistor and includes one or more compensating thin film transistors and compensating capacitors. At this time, configurations and structures of the compensating thin film transistor and the compensating capacitor are not limited, but may vary depending on a compensating method.

The non-display area NA of the substrate 110 is an area where no image is displayed and various wiring lines and circuits for driving the display unit disposed in the display area DA are disposed.

The pad area PA of the non-display area NA of the substrate 110 is an area where various wiring lines and circuits for receiving, with an external power, a data driving signal or transmitting and receiving a touch signal are disposed. In the pad area PA, an external module, for example, a driving IC such as a data driver IC (integrated circuit) or a gate driving IC may be located. The driving IC disposed in the pad area PA is connected to a plurality of signal lines and is connected to the plurality of data lines DL or the plurality of gate lines GL disposed in the display area DA through a plurality of signal lines. That is, the driving IC disposed in the pad area PA is electrically connected to each of the plurality of pixels P.

The bending area BA in which a part of the non-display area NA is bent in one direction is located between the display area DA and the pad area PA in the non-display area NA.

The non-display area NA is not an area where the images are displayed so that the non-display area does not need to be visible from a front surface of the display panel DP. Therefore, a partial area of the non-display area NA of the substrate 110 may be bent toward the rear surface of the display panel DP and for example, may be bent to the rear direction (that is, −Z axis) of the display panel DP so that one edge of the substrate 110 has a predetermined curvature. In this case, the pad area PA may be located so as to overlap the display area DA on the rear surface of the display panel DP. By doing this, the non-display area NA may be reduced while ensuring an area for the wiring line and the driving circuit.

The cover layer CL is disposed so as to cover the front surface of the display panel DP to protect the display panel DP from the external shock. The cover layer CL may be formed of cover glass, tempered glass, and tempered plastic, but is not limited thereto.

An edge portion of the cover layer CL may have a curvature portion or a curved portion bent in the rear direction (that is, the −Z axis) of the display panel DP. By doing this, the cover layer CL may be disposed so as to cover to a side area of the display panel DP and protect not only the front surface of the display panel DP, but also the side surface from the external shock.

The cover layer CL may be formed with a transparent material so as to overlap the display area DA of the substrate 110 of the display panel DP. For example, the cover layer CL may be formed of a cover glass of a transparent plastic material or a transparent glass material which transmits the image, but is not limited thereto.

A front surface of the display panel DP is disposed below the cover layer CL and the display area DA and the non-display area NA of the substrate 110 of the display panel DP may be applied also to the cover layer CL in the same way. That is, the area of the cover layer CL in which the image is transmitted is a display area and an area which encloses the display area and does not allow the image to transmit may be a non-display area.

The optical area 120 is disposed on the front surface of the display panel DP and suppresses the reflection of the external light to improve visibility and a contrast ratio with respect to an image which is displayed on the display panel DP.

The third adhesive layer 130 is disposed between the cover layer CL and the optical layer 120 to bond the cover layer CL and the optical layer 120. The third adhesive layer 130 overlaps the display area DA of the substrate 110 and uses a material which allows the image of the display panel DP to transmit. For example, the third adhesive layer 130 may be formed of an optical clear adhesive (OCA), and optical clear resin (OCR), or a pressure sensitive adhesive (PSA), but is not limited thereto.

On a lower surface of the non-display area (for example, an edge area) of the cover layer CL, a light shielding unit which blocks various circuits, wiring lines, and structures disposed in the non-display area NA of the display panel DP from being visible to the user may be disposed. The light shielding unit is formed of a material which absorbs light and for example, may be formed of a black matrix, or formed by printing with a black ink, but is not limited thereto.

The back plate 400 is disposed below the substrate 110.

The back plate 400 may not be disposed in a portion which overlaps the bending area BA. At this time, the back plate 400 includes a first plate 410 which is disposed so as to overlap the display area DA below the substrate 110 and a second plate 420 which is disposed so as to overlap the pad area PA below the substrate 110.

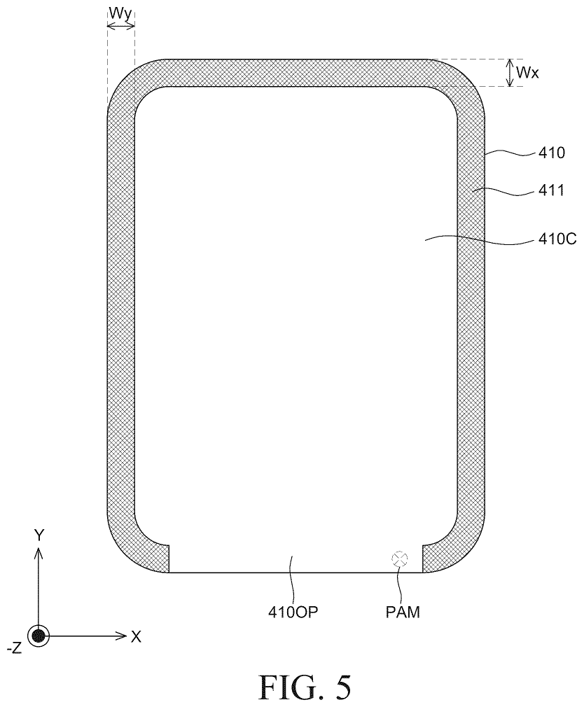

The display apparatus 100 according to the exemplary embodiment of the present disclosure includes a black layer disposed on the bottom surface of the first plate 410 to suppress the damage and the stain defect of the panel due to the exposure to the external light of the rear surface of the display panel DP. The black layer for blocking the exposure to the external light will be described in detail below with reference to FIGS. 5 to 16.

The first plate 410 and the second plate 420 may be formed of plastic thin films having rigidity. For example, the first plate 410 and the second plate 420 may be configured by polyethylene terephthalate (PET), polyimide (PI), polyethylene naphthalate (PEN), but are not limited thereto. The first plate 410 and the second plate 420 may be formed of the same material with the same thickness, but are not limited thereto.

With respect to the shape of the substrate 110 which is not bent in the bending area BA, the first plate 410 is coupled to the display area DA of the rear surface of the substrate 110. Therefore, the display area DA may be maintained in a flat state while supplementing the rigidity of the substrate 110.

With respect to the shape of the substrate 110 which is not bent in the bending area BA, the second plate 420 is coupled to the pad area PA of the rear surface of the substrate 110. Therefore, the pad area PA may be maintained in a flat state while supplementing the rigidity of the substrate 110.

With respect to the shape of the substrate 110 which is bent in the bending area BA, the second plate 420 is disposed between the first plate 410 disposed on the display area DA of the rear surface of the substrate 110 and the pad area PA of the rear surface of the substrate 110. At this time, the second adhesive layer 440 is disposed between the first plate 410 and the second plate 420 to bond the first plate 410 and the second plate 420 to fix the second plate 420 to the first plate 410.

The second adhesive layer 440 may be a double-sided tape having adhesive force, but is not limited thereto. For example, the second adhesive layer 440 is formed with a foam tape or a foam pad having adhesive force to relieve the shock.

One surface of the second adhesive layer 440 is attached onto a bottom surface of the first plate 410. Further, in order to dispose and fix the second plate 420 below the substrate 110 of the display panel DP, the second plate 420 is connected to or attached onto the bottom surface of the pad area PA of the substrate 110 and the bending area BA of the substrate 110 is bent to attach or fix the second plate 420 to the other surface of the second adhesive layer 440. Accordingly, the second plate 420 is disposed between the first plate 410 disposed below the display area DA of the substrate 110 and the bottom surface of the pad area PA of the substrate 110.

When the second plate 420 is fixed to the second adhesive layer 440, an outer portion which is a top surface of the substrate 110 in the bending area BA is exposed to the outside. Further, an inner portion which is a bottom surface of the substrate 110 is disposed so as to be opposite to a side surface of the first plate 410, a side surface of the second adhesive layer 440, and a side surface of the second plate 420.

In a state in which the substrate 110 is bent in the bending area BA, a tensile force higher than that of an existing state is applied to an outer portion of the substrate 110 with a reduced radius of curvature and a compressive force higher than that of the existing state is applied to an inner portion of the substrate 110. When the external shock is applied to the bending area BA of the substrate 110 to which the higher compressive force and tensile force are applied as described above, the bending area BA is deformed so that the substrate 110 and the signal line are cracked or damaged. In order to suppress this problem, the reinforcement member 140 may be disposed in an outer portion (that is, a top surface) of the bending area BA of the substrate 110.

Further, in order to increase the flexibility of the display panel DP, in the bending area BA of the substrate 110, some of other components (for example, the back plate 400) excluding the substrate 110 and the signal line is removed so that the rigidity may be lowered. The reinforcement member 140 supplements the rigidity of the bending area BA from which other components are removed.

The reinforcement member 140 extends to the bending area BA and at least a partial area of the pad area PA to cover the front surface of the substrate 110.

The reinforcement member 140 includes resin. For example, the reinforcement member 140 includes an ultraviolet (UV) curable acrylic resin or a thermosetting resin, but is not limited thereto, and various materials may be used. The reinforcement member 140 is formed of a cured resin that has undergone a curing process after applying the resin. For example, when the UV curable resin is used for the reinforcement member 140, UV ray is irradiated to cure the reinforcement member and when the thermosetting resin is used for the reinforcement member 140, heat is applied to cure the reinforcement member. For example, the reinforcement member 140 may be a micro cover layer (MCL).

Further, the reinforcement member 140 covers various signal lines disposed between an encapsulation unit which is disposed to a part of the non-display area NA from the display area DA of the substrate 110 and the pad area PA of the substrate 110. The reinforcement member 140 protects the signal line from the external shock and suppresses the permeation of moisture.

On the pad area PA of the substrate 110, various signal lines connected to the pixel P and the pad unit connected to each signal line are disposed. The pad unit includes a data pad which is electrically connected to the data line DL and a gate pad which is electrically connected to the gate line GL.

A controller which is electrically connected to the pad unit is disposed on the display area DA of the rear surface of the substrate 110. The controller is mounted in the printed circuit board 500 to be disposed below the first plate 410.

For example, the controller may be a timing controller 152, but is not limited thereto, and may be a control device which performs various other control functions together with the timing controller 152. The controller may be implemented by various circuits or electronic components, such as an integrated circuit (IC), a field programmable gate array (FPGA), an application specific integrated circuit (ASIC), or a processor.

On the rear surface of the substrate 110, the pad unit on the pad area PA and the controller mounted in the printed circuit board 500 on the display area DA are electrically connected through the flexible film unit 150.

In the flexible film unit 150, the driving IC, such as a data driver IC or a gate driver IC may be located. For example, the driving IC may be mounted in the flexible film as a chip on film (COF) type. Alternatively, the driving IC may be a flexible circuit, such as a flexible printed circuit (FPC). Further, the driving IC may be bonded directly to the pad units above the substrate 110 by the chip on glass (COG) process.

The first adhesive layer 430 is disposed between the printed circuit board 500 and the first plate 410 to bond the printed circuit board 500 and the first plate 410. For example, the first adhesive layer 430 may be formed of a pressure sensitive adhesive (PSA), but is not limited thereto.

In the meantime, when the display panel DP is exposed to the external light from the rear surface, in the display panel, there may be a luminance deviation between an area which is consistently affected by exposed light and an area which is not affected by the exposed light. Therefore, for example, stain defects, such as shadow mura may occur. In order to suppress this problem, a black layer is disposed on a bottom surface of the first plate 410 below the display panel DP according to the exemplary embodiment of the present disclosure.

Hereinafter, a structure in which the black layer is disposed on the bottom surface of the first plate 410 will be described with reference to FIGS. 5 to 16.

FIG. 5 is a plan view of a first plate as seen from a rear surface of a display panel according to an exemplary embodiment of the present disclosure.

Referring to FIG. 5, a black layer 411 with a predetermined width is disposed along an edge area of the bottom surface of the first plate 410. The black layer 411 is a light shielding layer and for example, may be a black ink layer. For example, ink including a black material which blocks light is directly printed on the bottom surface of the first plate 410 by means of a silk screen printing process to have predetermined widths (Wy, Wx) and thickness to dispose the black ink layer 411 in a predetermined position of the bottom surface of the first plate 410. The ink material of the black ink layer 411 may have a characteristic that the ink material is not decomposed under a specific environmental condition (for example, a high temperature and high humidity environment). Hereinafter, an example that the black layer 411 according to the exemplary embodiment of the present disclosure is a black ink layer will be described.

The first plate 410 has the same or similar size to the display area DA of the substrate 110 and the surrounding area which encloses the display area DA and is disposed such that a center point of the first plate 410 is aligned with a center point of the display area DA of the substrate 110.

A part of the edge area of the bottom surface of the first plate 410 may be an open area 410OP which is not printed with the black ink layer 411, but exposes the bottom surface of the first plate 410 as it is (hereinafter, referred to as a “first open area”). For example, the edge area on the bottom surface of the first plate 410 includes a first area on which the black ink layer 411 is printed and the second area (that is, a first open area 410OP) on which the black ink layer 411 is not printed.

Further, an area excluding the edge area of the bottom surface of the first plate 410, for example, a center area may be an open area 410C which is not printed with the black ink layer 411, but exposes the bottom surface of the first plate 410 as it is (hereinafter, referred to as a “second open area”).

For example, a panel alignment mark PAM disposed in one position of the rear surface of the substrate 110 of the display panel DP may be exposed to be identified, through the first open area 410OP of the bottom surface of the first plate 410.

The panel alignment mark PAM is located at a point exposed to the outside of the substrate, for example, is located in a corner direction of the outermost portion of the substrate 110 to be recognized by the naked eye or a camera, during the cell pre-process and post-process and a module process during the process. In FIG. 5, an example that the panel alignment mark PAM is disposed to be close to the corner in the edge area of the rear surface of the substrate 110 is illustrated.

For example, the panel alignment mark PAM is configured by a metal layer having a specific shape and an organic film which covers the metal layer and protrudes from the rear surface of the substrate 110 with an embossing shape, but is not limited thereto.

The first plate 410 may be formed of a transparent material to transmit the panel alignment mark PAM disposed on the rear surface of the substrate 110 to be identified and for example, may be configured by a transparent polyethylene terephthalate (PET) film, but is not limited thereto.

As described above, as the black ink layer 411 is disposed so as to enclose the edge area on the bottom surface of the first plate 410, light exposure from the rear surface of the display panel DP is blocked to suppress the panel damage and the stain defects. Further, a part of the edge area of the bottom surface of the first plate 410 is not printed with the black ink layer 411, but is configured as the first open area 410OP to allow the panel alignment mark PAM disposed on the rear surface of the substrate 110 of the display panel DP to transmit the first plate 410 which is a transparent material to be recognizable. By doing this, the panel alignment mark PAM required to bend the display panel DP is exposed to guide the bending of the display panel DP to suppress the misalignment of components disposed in the bending area BA of the substrate 110. For example, when the substrate 110 is bent, a part of the flexible film unit 150 is disposed so as to overlap the first open area 410OP of the bottom surface of the first plate 410.

In the meantime, the first adhesive layer 430 which bonds the first plate 410 and the printed circuit board 500 is disposed in the second open area 410C which is a center area of the bottom surface of the first plate 410.

For example, the black ink layer 411 is disposed on the rear surface of the substrate 110 so as to overlap the surrounding area. At this time, the black ink layer 411 may be disposed along the edge of the first adhesive layer 430 to be spaced apart from the first adhesive layer 430 by a predetermined distance. That is, the widths (Wx, Wy) of the black ink layer 411 may be set depending on the size of the first adhesive layer 430. In order to increase a light blocking efficiency from the rear surface of the display panel DP, the black ink layer 411 is set to be disposed as close as possible to the first adhesive layer 430 or overlap the outermost portion of the first adhesive layer 430 by a predetermined area.

Accordingly, the second open area 410C of the bottom surface of the first plate 410 has the same shape as a shape of the first adhesive layer 430 and has an area almost similar to the area of the first adhesive layer 430. By doing this, the placement position of the first adhesive layer 430 is guided below the first plate 410 and the placement position of the printed circuit board 500 which is bonded through the first adhesive layer 430 is also guided, and the misalignment while placing the first adhesive layer 430 may be suppressed. Further, the black ink layer 411 is directly printed on the bottom surface of the first plate 410 to reduce the manufacturing cost as compared with the case that a separate light shielding film, such as a black film tape is attached to the first plate 410. Further, the misalignment between the light shielding film which is separately attached and the first adhesive layer 430 is also suppressed.

The first adhesive layer 430 disposed on the bottom surface of the first plate 410 is disposed so as to correspond to a size and a shape of the printed circuit board 500 in the second open area 410C of the first plate 410 and may have various shapes.

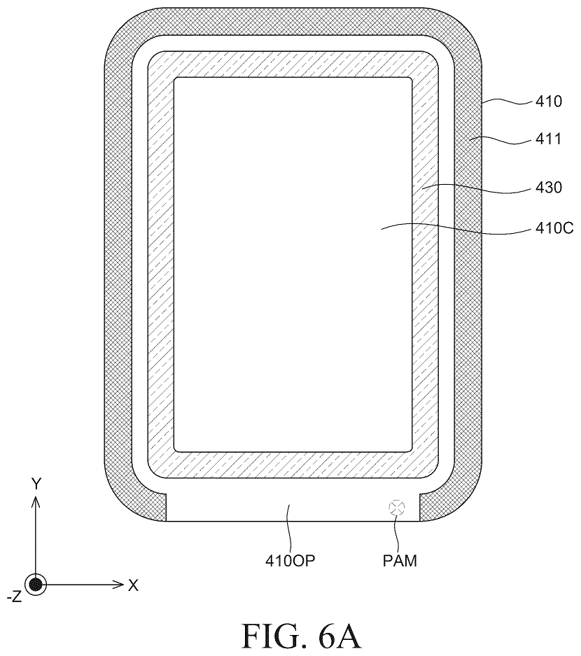

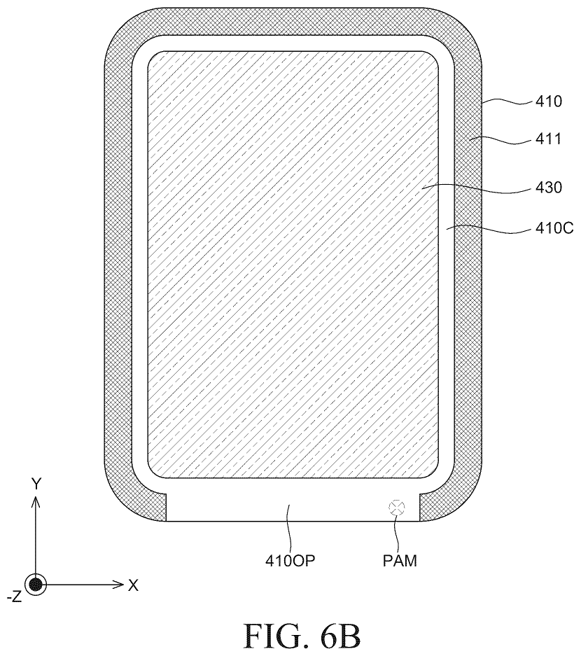

FIG. 6A is a plan view illustrating an example of an adhesive layer disposed below a first plate according to an exemplary embodiment of the present disclosure. FIG. 6B is a plan view illustrating another example of an adhesive layer disposed below a first plate according to an exemplary embodiment of the present disclosure.

For example, as illustrated in FIG. 6A, the first adhesive layer 430 may be disposed to have a ring shape with a predetermined width along a circumference of the second open area 410C of the first plate 410. As another example, as illustrated in FIG. 6B, the first adhesive layer 430 has the same shape as a shape of the second open area 410C of the first plate 410. The first adhesive layer is disposed to be filled in all the areas in the second open area 410C excluding an area in which the black ink layer 411 is disposed or disposed to be filled in all the areas spaced apart from the black ink layer 411 by a predetermined distance. Accordingly, the adhesive strength between the first adhesive layer 430 and the printed circuit board 500 may be increased. However, a size and a shape of the first adhesive layer 430 according to the exemplary embodiment of the present disclosure are not limited those illustrated in FIGS. 6A and 6B.

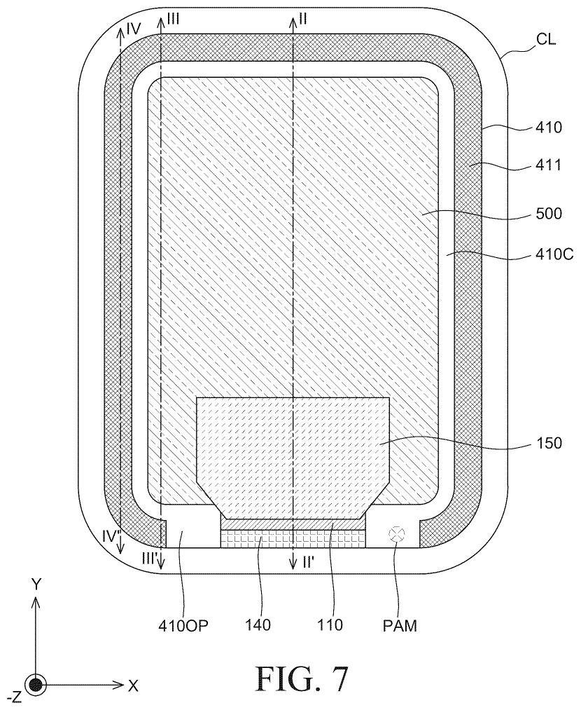

Hereinafter, a placement structure of components and a printing position of the black ink layer 411 when the substrate 110 of the display panel DP is bent in the display apparatus 100 according to the exemplary embodiment of the present disclosure will be described in more detail with reference to FIGS. 7 to 10.

FIG. 7 is a rear view of a display device including a first plate according to an exemplary embodiment of the present disclosure.

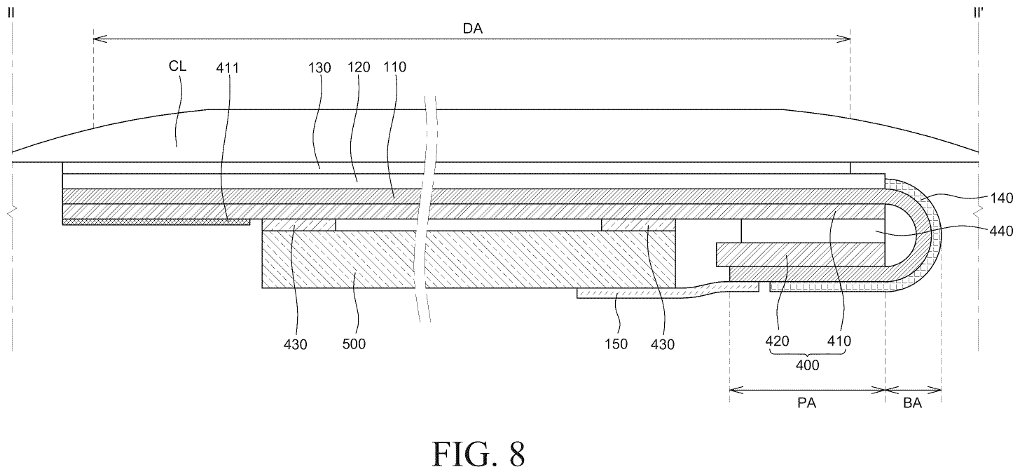

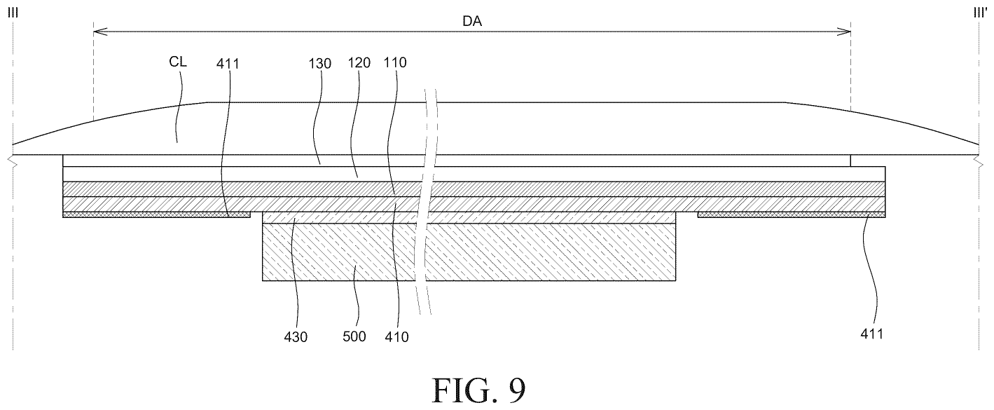

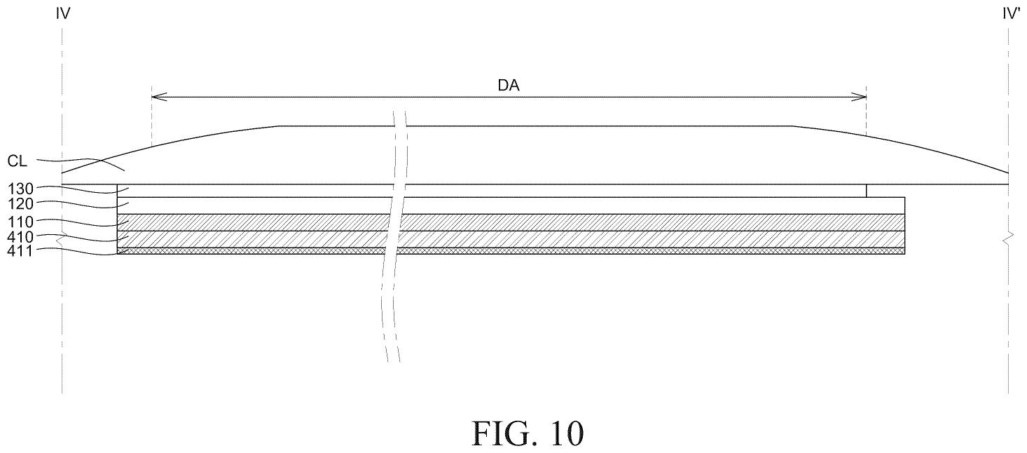

FIG. 8 is a cross-sectional view taken along the line II-II′ of FIG. 7 according to an exemplary embodiment of the present disclosure, FIG. 9 is a cross-sectional view taken along the line III-III′ of FIG. 7 according to an exemplary embodiment of the present disclosure, and FIG. 10 is a cross-sectional view taken along the line IV-IV′ of FIG. 7 according to an exemplary embodiment of the present disclosure.

Referring to FIGS. 7 and 8 together, in the plan view, in an area which overlaps the first open area 410OP along one direction (that is, a Y-direction) on the bottom surface of the first plate 410, the black ink layer 411 is printed only in one edge area of the bottom surface of the first plate 410. The remaining area is an open area through which the bottom surface of the first plate 410 is exposed.

However, in the second open area 410C in which the black ink layer 411 is not printed in the first plate 410, the first adhesive layer 430 and the printed circuit board 500 are disposed so that the external light from the rear surface of the display panel DP is not incident or minimized in the corresponding area.

Further, in the first open area 410OP in which the black ink layer 411 is not printed in the first plate 410, the second adhesive layer 440, the second plate 420, the pad area PA of the substrate 110, and a part of the flexible film unit 150 which is connected between the pad area PA of the substrate 110 and the printed circuit board 500 are disposed to overlap. Accordingly, the external light from the rear surface of the display panel DP is not incident or minimized. At this time, the size of the first open area 410OP may be minimized in a state in which the area through which the panel alignment mark PAM is exposed is ensured. For example, in an edge area including the first open area 410OP of the first plate 410, the black ink layer 411 is disposed as close as possible to the pad area PA of the substrate 110 and the flexible film unit 150 or is disposed to overlap the outermost portions of the pad area PA of the substrate 110 and the flexible film unit 150 by a predetermined area.

Referring to FIGS. 7 and 9 together, in the plan view, in an area which overlaps an area between the first open area 410OP and the outermost portion of the first plate 410 along one direction (that is, a Y-direction) on the bottom surface of the first plate 410, the black ink layer 411 is printed only in one side of one edge area of the bottom surface of the first plate 410 and the other side of the edge area opposite thereto. The remaining area is an open area through which the bottom surface of the first plate 410 is exposed.

However, in the second open area 410C in which the black ink layer 411 is not printed in the first plate 410, the first adhesive layer 430 and the printed circuit board 500 are disposed so that the external light from the rear surface of the display panel DP is not incident or minimized in the corresponding area.

Referring to FIGS. 7 and 10 together, in the plan view, in an area overlapping an area of the outermost portion of the first plate 410 along one direction (that is, the Y direction) on the bottom surface of the first plate 410, the black ink layer 411 is printed in the entire edge area of the bottom surface of the first plate 410.

As described above, the black ink is directly printed in the edge area of the bottom surface of the first plate 410 disposed on the rear surface of the display panel DP to dispose the black ink layer 411. By doing this, the exposure to the external light from the rear surface of the display panel DP is blocked to suppress the panel damage and the stain defects. Further, the first plate 410 is formed of a transparent material to transmit the panel alignment mark PAM disposed on the bottom surface of the display panel DP to be identified and an open area in which the black ink layer 411 is not formed in an area which overlaps the panel alignment mark PAM is included in the edge area of the first plate 410. Therefore, the panel alignment mark PAM required to bend the display panel DP is exposed to guide the bending of the display panel DP to suppress the misalignment of the components disposed in the bending area BA of the substrate 110. Further, the black ink layer 411 is disposed along a shape of the first adhesive layer 430 in the edge area of the bottom surface of the first plate 410 to guide the placement position of the first adhesive layer 430 below the first plate 410, thereby suppressing the misalignment when the first adhesive layer 430 is disposed.

The shape of the black ink layer 411 which is printed on the bottom surface of the first plate 410 is not limited to that described with reference to FIGS. 5 to 10.

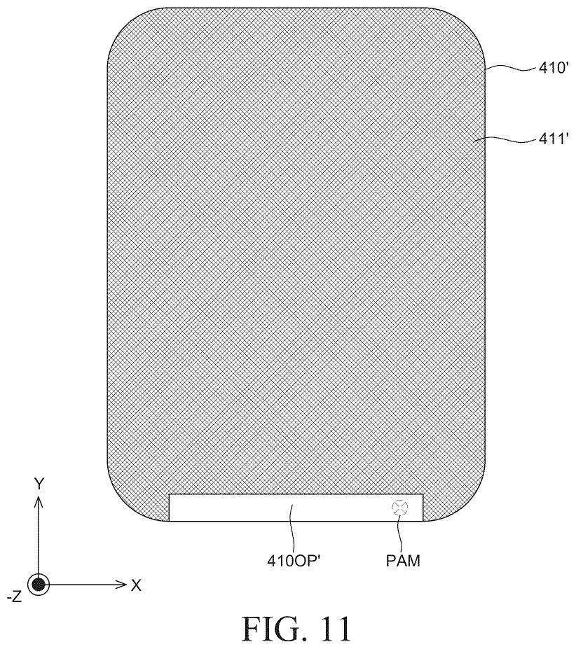

Hereinafter, a structure in which the black ink layer is disposed in the first plate of the display apparatus according to another exemplary embodiment of the present disclosure will be described in detail. However, the display apparatus according to another exemplary embodiment of the present disclosure includes components and features thereof which are substantially the same as or similar to those of the display device according to the exemplary embodiment of the present disclosure except for the structure in which the black ink layer is disposed on the first plate. Therefore, for the convenience of description, description of duplicate components and features thereof will be omitted. Further, among components of the display apparatus according to another exemplary embodiment of the present disclosure illustrated in FIGS. 11 to 16, components denoted by the same reference numeral as the components of the display apparatus according to the exemplary embodiment of the present disclosure which have been described above in FIGS. 5 to 10 may refer to the substantially same components.

FIG. 11 is a plan view of a first plate as seen from a rear surface of a display panel according to another exemplary embodiment of the present disclosure.

Referring to FIG. 11, a black ink layer 411′ is disposed in the entire bottom surface of the first plate 410′ except for the first open area 410OP′ included in one side of the edge area. For example, as compared with the first plate 410 according to one exemplary embodiment of the present disclosure which has been described above with reference to FIG. 5, the black ink layer 411′ is disposed not only in the edge area of the bottom surface of the first plate 410′ except for the first open area 410OP′, but also in the second open area 410C which is a center area. Accordingly, the first adhesive layer 430 is disposed on the bottom surface of the black ink layer 411′ on the bottom surface of the first plate 410′. At this time, in the plan view, there is no interval between the black ink layer 411′ and the first adhesive layer 430. As described above, as the black ink layer 411′ is disposed on the entire bottom surface of the first plate 410′ except for the first open area 410OP′, the convenience during the printing process of the black ink layer 411′ is increased and the external light blocking efficiency from the rear surface of the display panel DP is further increased.

Further, as illustrated in FIG. 11, in the first open area 410OP′ of the first plate 410′, the black ink layer 411′ is not printed, but the bottom surface of the first plate 410′ is exposed as it is. Therefore, the panel alignment mark PAM disposed in one position of the rear surface of the substrate 110 of the display panel DP may be identified through the first open area 410OP′.

The first adhesive layer 430 disposed on the bottom surface of the first plate 410′ is disposed so as to correspond to a size and a shape of the printed circuit board 500 in a center area having a predetermined area based on the center point of the first plate 410′ and may have various shapes.

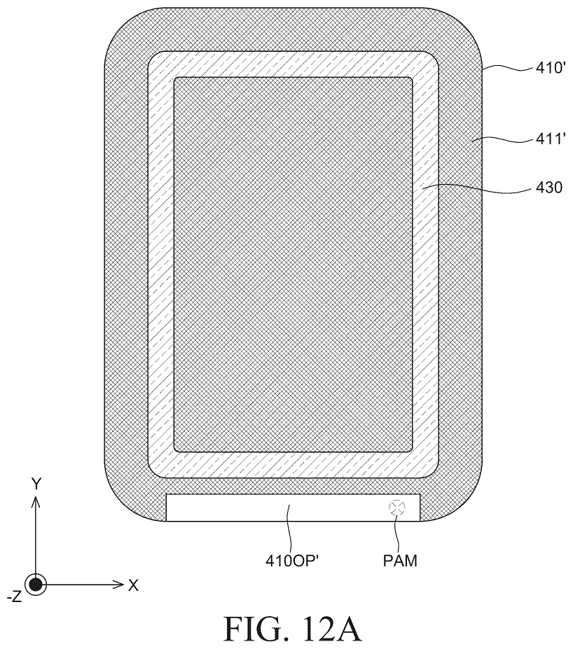

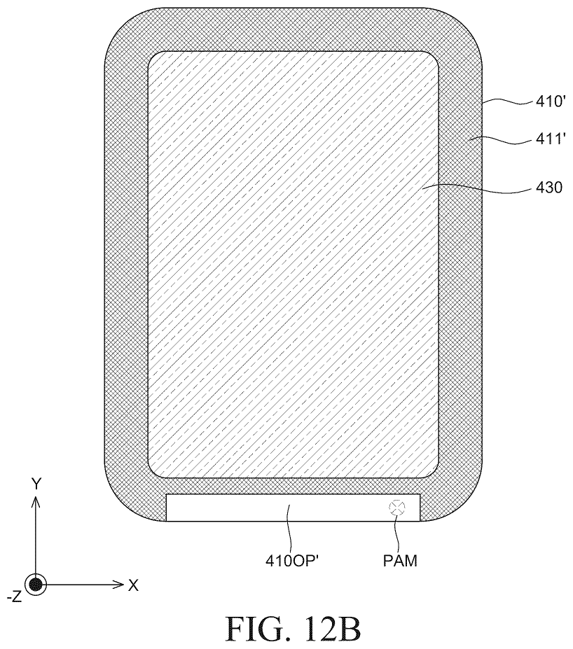

FIG. 12A is a plan view illustrating an example of an adhesive layer disposed below a first plate according to another exemplary embodiment of the present disclosure. FIG. 12B is a plan view illustrating another example of an adhesive layer disposed below a first plate according to another exemplary embodiment of the present disclosure.

For example, as illustrated in FIG. 12A, the first adhesive layer 430 may be disposed to have a ring shape with a predetermined width in a position spaced apart from an edge of the first plate 410 by a predetermined interval. At this time, a partial area close to the center point on the bottom surface of the first plate 410′ is exposed from the first adhesive layer 430. As another example, as illustrated in FIG. 12B, the first adhesive layer 430 may be disposed to be filled in all the area in a position spaced apart along an edge of the first plate 410 by a predetermined interval. However, a size and a shape of the first adhesive layer 430 according to another exemplary embodiment of the present disclosure are not limited to those illustrated in FIGS. 12A and 12B.

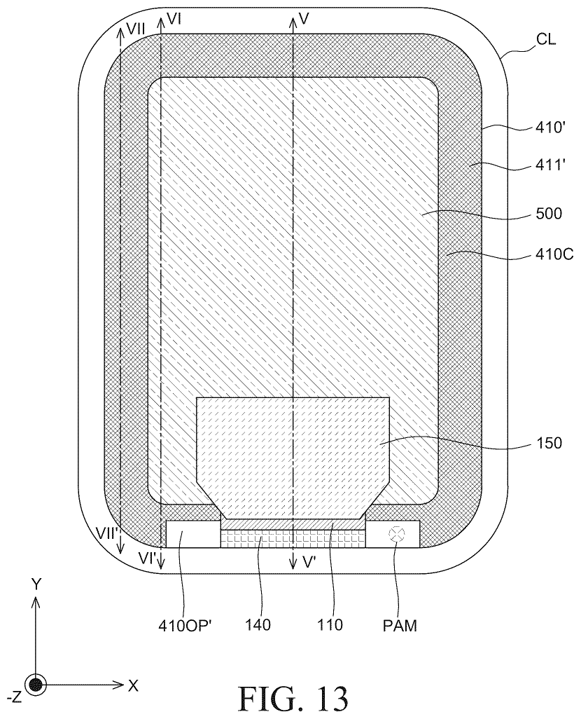

Hereinafter, a placement structure of components and a printing position of the black ink layer 411′ when the substrate 110 of the display panel DP is bent in the display apparatus according to another exemplary embodiment of the present disclosure will be described in more detail with reference to FIGS. 13 to 16.

FIG. 13 is a rear view of a display device including a first plate according to another exemplary embodiment of the present disclosure.

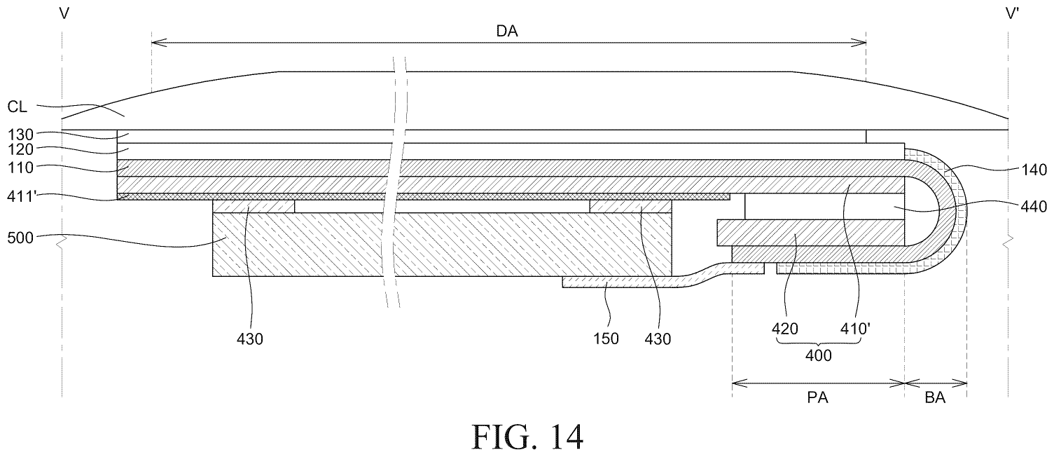

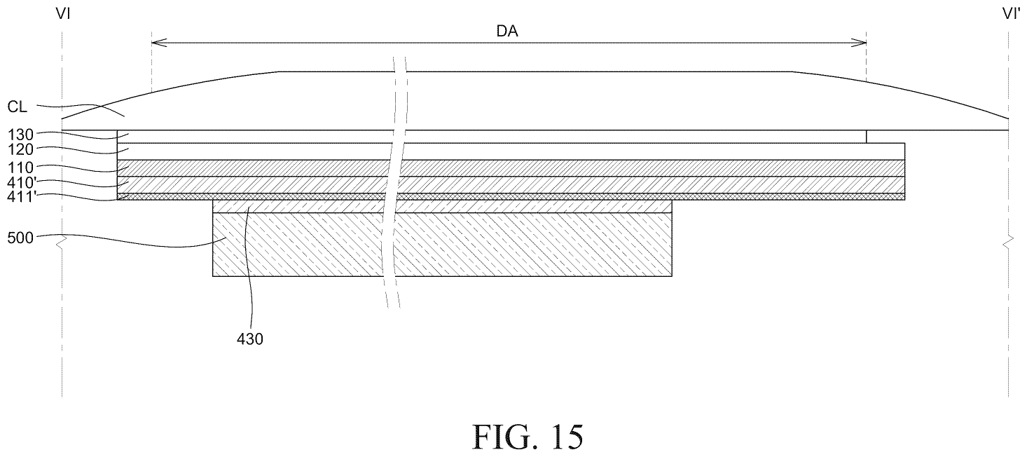

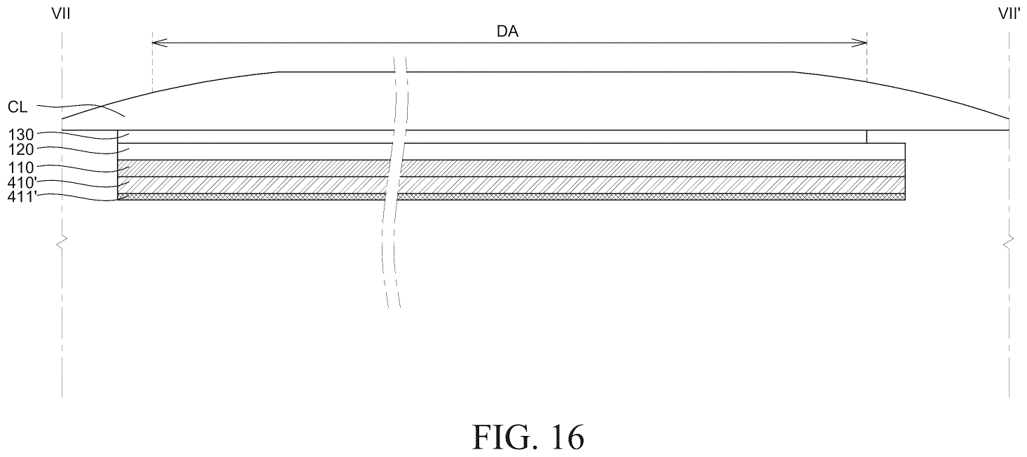

FIG. 14 is a cross-sectional view taken along the line V-V′ of FIG. 13 according to an exemplary embodiment of the present disclosure, FIG. 15 is a cross-sectional view taken along the line VI-VI′ of FIG. 13 according to an exemplary embodiment of the present disclosure, and FIG. 16 is a cross-sectional view taken along the line VII-VII′ of FIG. 13 according to an exemplary embodiment of the present disclosure.

Referring to FIGS. 13 and 14 together, in an area overlapping the first open area 410OP′ along one direction (that is, the Y direction) on the bottom surface of the first plate 410′, the black ink layer 410 is printed not only in the edge area of the bottom surface of the first plate 410′, but also in the entire surface excluding the first open area 410OP′.

In the first open area 410OP′ in which the black ink layer 411′ is not printed in the first plate 410′, the second adhesive layer 440, the second plate 420, the pad area PA of the substrate 110, and a part of the flexible film unit 150 which is connected between the pad area PA of the substrate 110 and the printed circuit board 500 are disposed to overlap. At this time, at least one of the second adhesive layer 440, the second plate 420, the pad area PA of the substrate 110, and the flexible film unit 150 which is connected between the pad area PA of the substrate 110 and the printed circuit board 500 may at least partially overlap the black ink layer 411′ in a portion excluding a portion overlapping the first open area 410OP′ in the plan view.

Referring to FIGS. 13 and 15 together, in the plan view, in the entire area overlapping an area between the first open area 410OP′ and an outermost portion of the first plate 410′ along one direction (that is, the Y direction) on the bottom surface of the first plate 410′, the black ink layer 411′ is printed.

Referring to FIGS. 13 and 16 together, in the plan view, also in an entire area overlapping an area of the outermost portion of the first plate 410′ along one direction (that is, the Y direction) on the bottom surface of the first plate 410′, the black ink layer 411′ is printed.

As described above, the black ink is directly printed in the entire surface excluding a partial area included in one side of the edge area of the bottom surface of the first plate 410′ disposed on the rear surface of the display panel DP to dispose the black ink layer 411′. By doing this, the exposure to the external light from the rear surface of the display panel DP is blocked to suppress the panel damage and the stain defects. Further, the first plate 410′ is formed of a transparent material to transmit the panel alignment mark PAM disposed on the rear surface of the display panel DP to be identified and an open area in which the black ink layer 411′ is not formed in an area which overlaps the panel alignment mark PAM is included in one side of the edge area of the first plate 410′. Therefore, the panel alignment mark PAM required to bend the display panel DP is exposed to guide the bending of the display panel DP, thereby suppressing the misalignment of the components disposed in the bending area BA of the substrate 110.

The display apparatus according to the exemplary embodiment of the present disclosure may be applicable to a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, a personal digital assistant, an electronic book, a portable multimedia player (PMP), a personal digital assistant (PDA), an MP3 player, a mobile medical apparatus, a desktop PC, a laptop PC, a netbook computer, a workstation, a navigation, a navigation for a vehicle, a display apparatus for a vehicle, an apparatus for a vehicle, a theatrical device, a theatrical display, a television, a wallpaper device, a signage device, a game device, a notebook, a monitor, a camera, a camcorder, and a consumer electronics device. Further, the display apparatus according to the exemplary embodiment of the present disclosure is also applied to an organic light emitting illumination device or an inorganic light emitting illumination device.

The exemplary embodiments of the present disclosure can also be described as follows:

According to an aspect of the present disclosure, there is provided a display apparatus. The display apparatus includes a display panel including a substrate in which a display area in which a plurality of pixels is disposed and a non-display area in an outer periphery of the display area are defined. The display apparatus further includes a first plate disposed below the display panel. The display apparatus further includes a black layer disposed on a bottom surface of the first plate. The display apparatus further includes a printed circuit board disposed below the first plate. The display apparatus further includes a first adhesive layer which bonds the first plate and the printed circuit board. A bottom surface of the first plate includes a center area and an edge area which encloses the center area and includes a first area and a second area and the black layer is disposed in the first area among the first area and the second area.

The black layer may be a black ink layer in which an ink including a black material is printed on a bottom surface of the first plate.

The black layer may be disposed in the first area of the edge area among the center area and the edge area.

The first adhesive layer may be disposed in at least a part of the center area.

The first adhesive layer may be disposed in the center area to have a ring shape.

In the plan view, the black layer may be spaced apart from an edge of the first adhesive layer by a predetermined interval.

The black layer may be further disposed in the center area.

The first adhesive layer may be disposed on a bottom surface of the black layer disposed in the center area.

The first adhesive layer may be disposed in the center area to have a ring shape.

The display panel may include a panel alignment mark disposed on the bottom surface of the substrate and the panel alignment mark may be disposed so as to overlap the second area.

The non-display area of the substrate may include a surrounding area which encloses the display area, a bending area which extends from one side of the surrounding area and is bent, and a pad area which extends from the bending area and is disposed below the display area as the substrate is bent in the bending area. The display apparatus may further include a second plate which is disposed in the pad area below the display panel; and a second adhesive layer which bonds the second plate and the first plate.

The display apparatus may further include: a flexible film unit which electrically connects a controller disposed in the printed circuit board and the pad unit disposed on the pad area of the substrate.

The flexible film unit may be disposed so as to overlap the second area.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display apparatus, comprising:
a display panel including a substrate, the substrate including a display area in which a plurality of pixels are disposed and a non-display area in an outer periphery of the display area;
a first plate below the display panel;
a black layer on a bottom surface of the first plate;
a printed circuit board below the first plate; and
a first adhesive layer bonding the first plate and the printed circuit board,
wherein a bottom surface of the first plate includes a center area and an edge area which encloses the center area and includes a first area and a second area,
wherein the black layer is in the first area among the first area and the second area.

2. The display apparatus according to claim 1, wherein the black layer is a black ink layer in which an ink including a black material is printed on the bottom surface of the first plate.

3. The display apparatus according to claim 1, wherein the black layer is in the first area of the edge area among the center area and the edge area.

4. The display apparatus according to claim 3, wherein the first adhesive layer is in at least a part of the center area.

5. The display apparatus according to claim 4, wherein the first adhesive layer is in the center area and has a ring shape.

6. The display apparatus according to claim 4, wherein in a plan view, the black layer is spaced apart from an edge of the first adhesive layer by a predetermined interval.

7. The display apparatus according to claim 4, wherein in a plan view of the display apparatus, the black layer overlaps an outermost portion of the first adhesive layer by a predetermined area.

8. The display apparatus according to claim 1, wherein the black layer is disposed in the center area and the first area of the edge area among the center area and the edge area.

9. The display apparatus according to claim 8, wherein the first adhesive layer is on a bottom surface of the black layer disposed in the center area.

10. The display apparatus according to claim 9, wherein the first adhesive layer is in the center area and has a ring shape.

11. The display apparatus according to claim 1, wherein the display panel includes a panel alignment mark on a bottom surface of the substrate and the panel alignment mark overlaps the second area of the edge area.

12. The display apparatus according to claim 11, wherein the first plate includes a transparent material.

13. The display apparatus according to claim 1, wherein the non-display area of the substrate includes a surrounding area enclosing the display area, a bending area extending from one side of the surrounding area and bending, and a pad area extending from the bending area and is below the display area as the substrate is bent in the bending area,
the display apparatus further comprising:
a second plate in the pad area below the display panel; and
a second adhesive layer bonding the second plate and the first plate.

14. The display apparatus according to claim 13, further comprising:
a flexible film unit electrically connecting a controller disposed in the printed circuit board and a pad unit disposed on the pad area of the substrate.

15. The display apparatus according to claim 14, wherein the flexible film unit overlaps the second area.

16. The display apparatus according to claim 13, further comprising:
a reinforcement member in an outer portion of the bending area.
